(19) United States
(12) Patent Application Publication
(10) Pub. No.: US 2002/0081799 A1
(43) Pub. Date: Jun. 27, 2002

(54) CONTACT FABRICATION METHOD FOR SEMICONDUCTOR DEVICE

(76) Inventor: DAE-YOUNG KIM, YICHEON-SHI (KR)

Correspondence Address: OLIFF & BERRIDGE, PLC, P.O. BOX 19928, ALEXANDRIA, VA, 22320, US

(21) Appl. No.: 09/220,702

(22) Filed: Dec. 24, 1998

(30) Foreign Application Priority Data
Dec. 27, 1997 (KR) 1997-75699

(51) Int. Cl. H01L 21/8238; H01L 21/8242

(52) U.S. Cl. 438/233

(57) ABSTRACT

A contact fabrication method for a semiconductor device is disclosed. The method includes the steps of forming a first interlayer insulation film on the front surface of the resultant structure and forming a contact hole for exposing the bit line contact plug of the memory cell array and a part of surface of the source or drain junction of the peripheral circuit, forming a bit line contacting with the bit line contact plug formed on the substrate of the memory cell array through the contact hole of the first interlayer insulation film and a source or drain junction surface of the peripheral circuit, forming a second interlayer insulation film on the upper portion of the resultant structure and planerizing the surface of the resultant structure, forming a contact hole on the planerized second interlayer insulation film, a part of the surfaces of the electric potential storing electrode contact plug of the memory cell array being exposed through the contact hole, and forming an electric potential storing electrode contacting with the electric potential storing electrode contact plug through the contact hole of the second interlayer insulation film.

### BACKGROUND OF THE INVENTION

1. Field of the Invention

The present invention relates to a contact fabrication method for a semiconductor device which makes it possible to implement a high integration of a semiconductor device by forming an electric potential storing electrode contact and a bit line contact contacting with an electric potential storing electrode contact plug and a bit line contact plug after forming the electric potential storing electrode contact plug and bit line contact plug contacting with a semiconductor substrate when forming an electric charge storing contact and bit line for thereby obtaining a substantial process margin with a neighboring layer in a limited area and forming a small contact in which a junction leakage current is small.

2. Description of the Conventional Art

The recent high integration trend of a semiconductor device is largely dependent on an advanced fineness technique of a pattern. During the fabrication processes of a semiconductor device, the fineness of a photoresist pattern generally used as a mask for an etching or ion implantation process is very important.

The resolution R of a photoresist pattern is in proportion to a wavelength λ of a light source of a reducing light exposurer and a fabrication margin k, respectively, and is in inverse proportion to the NA(Numerical Aperture) of a lens of the light exposurer.

[R=k·λ/NA, where R=resolution, λ=wavelength of light source, and NA=numerical aperture]

Here, in order to enhance a light resolution of the reducing light exposurer, it is needed to decrease the wavelength of the light source. For example, in the reducing light exposurer of a G-line and i-line having wavelengths of 436 and 365 nm, the limits of the process resolution are about 0.7 and 0.5 μm. In order to form a fine pattern of below 0.5 μm, a light exposurer using a far ultraviolet ray having a short wavelength, for example, such as a KrF laser having a wavelength of 248 nm, and an ArF laser of 193 nm, is used as a light source. In order to decrease the limit of the resolution, some methods are disclosed. Namely, a method for using a phase inversion mask as a light exposurer mask, a CEL(Contrast Enhancement Layer) method in which a thin film is formed on a wafer capable of enhancing an image contrast is disclosed, a TLR(Tri-Layer Resist) for forming an intermediate layer such as a SOG(Spin On Glass) between two photoresist films, and a method for selectively implanting silicon into an upper portion of the photoresist film are disclosed.

In addition, as a contact hole connecting upper and lower conductive wires is high-integrated, the size of the contact hole and a distance between the neighboring wires are decreased, and the aspect ratio of the contact hole is increased. Therefore, in the high integration semiconductor device having a multiple layer of conductive wires, the process margin is decreased for the reason that an accurate alignment is needed between the masks in the fabrication process for forming the contacts in the high integration semiconductor device.

In order to maintain a predetermined distance in the above-described contact hole, the masks are formed based on a misalignment tolerance when aligning the masks, a lens distortion during a light exposure process, a critical value variation during a mask fabrication and photoetching process, and a matching between the masks.

The conventional contact fabrication method for a semiconductor device will be explained.

First, a predetermined dopant is ion-implanted into a portion of the semiconductor substrate, so that the dopant is implanted into a well and a channel portion of a transistor and a device isolation portion. A device isolation oxide film is formed on a predetermined portion of the semiconductor substrate used as a device isolation region. A polycrystal silicon layer, a silicide film and a mask insulation film are sequentially formed on the remaining portions of the semiconductor substrate. Thereafter, the mask insulation film, the silicide film and the first polycrystal silicon layer are sequentially etched using a gate electrode patterning mask for thereby forming a gate electrode formed of a first polycrystal silicon layer pattern and a silicide film pattern and a mask insulation film pattern deposited on the upper portion of the same.

Next, a low density dopant layer, which is used as a LDD(Lightly Doped Drain) region, is formed on the semiconductor substrate at both side of the gate electrode, and the oxide film is etched based on a front side coating and front side anisotropic etching method by the CVD(Chemical Vapor Deposition) method, so that an insulation spacer is formed at the lateral walls of the first polycrystal silicon layer pattern, the silicide film pattern and the mask insulation film pattern.

Thereafter, a high density dopant region is formed in the semiconductor substrate at both sides of the spacer, and a second polysilicon layer on the front surface of the resultant structure.

The second polycrystal silicon layer formed on the device isolation oxide film and the mask insulation film is photo-etched, with the same remaining on the upper portion of the semiconductor substrate for thereby forming an interlayer insulation film on the front surface of the resultant structure.

The interlayer insulation film formed on the portion which is used as the contact on the semiconductor substrate is removed for thereby forming a bit line contact hole and an electric potential storing electrode contact hole. At this time, the second polycrystal silicon layer pattern becomes an etching barrier wall. The exposed second polycrystal silicon layer is removed, and an insulation spacer is formed at the lateral wall of the contact hole, and a bit line and electric potential storing electrode filled into the contact hole are formed.

In the above-described conventional contact fabrication method for a semiconductor device, as the high integration in which the distance between the gate electrodes connecting the word lines is decreased, the process margin for forming a contact electrode between the gate electrodes is decreased. In order to prevent a contact between the contact and the gate electrode, a spacer should be formed in the contact hole. However, the contact is too narrow, there is not enough space for forming the above-described spacer. When forming the spacer, the junction of the contact may be damaged, so that the yield and reliability of the device may be decreased.

### SUMMARY OF THE INVENTION

Accordingly, it is an object of the present invention to provide a contact fabrication method for a semiconductor device which overcomes the aforementioned problems encountered in the conventional art.

It is another object of the present invention to provide a contact fabrication method for a semiconductor device which is capable of enhancing a fabrication yield and reliability of the device by preventing a contact between a contact formed in a small area and a gate electrode by forming a bit line contact contacting with a bit line contact plug and an electric potential storing electrode contact plug and an electric potential storing electrode contact after forming the bit line contact plug and the electric potential storing electrode contact plug at a portion which is used for a bit line contact and electric potential storing electrode contact formation, decreasing a junction leakage current, and preventing a short circuit with an electroluminance display device by encapsulating the bit line using a nitride film.

In order to achieve the above objects, there is provided a contact fabrication method for a semiconductor device which includes the steps of forming a gate electrode formed of more than one conductive layer and a mask insulation film pattern self-aligned with the electrode on a semiconductor substrate on which the memory cell array and peripheral circuit are formed, forming a first spacer on a mask insulation film pattern of the substrate and a lateral wall of a gate electrode corresponding to the regions of the memory cell array, forming a source and drain junction on the memory cell array region exposed by the first spacer and the gate electrode, depositing a conductive film on the front surface of the substrate, patterning the conductive film, and forming a bit line contact plug and electric potential storing electrode contract plug contacting with the drain and source junction of the substrate of the memory cell array region, forming a second spacer on the mask insulation film pattern of the substrate corresponding to the region of the peripheral circuit and a lateral wall of the gate electrode, respectively, forming a source and drain junction at a region of the peripheral circuit exposed by the second spacer and mask insulation film pattern, forming a first interlayer insulation film on the front surface of the resultant structure and forming a contact hole for exposing the bit line contact plug of the memory cell array and a part of surface of the source or drain junction of the peripheral circuit, forming a bit line contacting with the bit line contact plug formed on the substrate of the memory cell array through the contact hole of the first interlayer insulation film and a source or drain junction surface of the peripheral circuit, forming a second interlayer insulation film on the upper portion of the resultant structure and planerizing the surface of the resultant structure, forming a contact hole on the planerized second interlayer insulation film, a part of the surfaces of the electric potential storing electrode contact plug of the memory cell array being exposed through the contact hole, and forming an electric potential storing electrode contacting with the electric potential storing electrode contact plug through the contact hole of the second interlayer insulation film.

More preferably, in the contact fabrication method for a semiconductor device according to the present invention, the conductive layer of a gate electrode is formed in a two-tier structure of a polycrystal silicon layer and a silicide layer. The first spacer and second spacer are formed using a silicon nitride film. In addition, the bit line and electric potential storing contact plug are formed using a polycrystal silicon layer. More preferably, the insulation film pattern of the gate electrode and the first spacer formed at the lateral wall of the same are used as an etching mask when forming the contact plug, for thereby forming a contact hole through which a part of the gate electrode conductive layer of the peripheral circuit is exposed when forming the contact hole of the first interlayer insulation film. In addition, a word line is formed in the contact hole so that a part of the conductive layer of the gate electrode of the peripheral circuit is exposed when forming the bit line. A thin insulation film is formed on the upper surfaces and lateral walls of the bit line and the word line.

In addition, in the contact fabrication method for a semiconductor device according to the present invention, a spacer formed of an insulation film is formed on an inner wall of the contact hole of the second interlayer insulation film after the contact hole, through which a part of the surface of the electric potential electrode contact plug of the memory cell array unit is exposed, is formed at the planerized second interlayer insulation film.

Therefore, in the present invention, even when the distance between the gate electrodes connecting the word lines is narrow, it is possible to prevent a contact between the gate electrode and the contact electrode by a bit line and electric potential storing electrode contact plug formed between the gate electrodes for thereby decreasing the junction leakage current and enhancing a reliability of the contact fabrication process and the fabrication yield.

Additional advantages, objects and other features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims as a result of the experiment compared to the conventional arts.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1 through 6 are cross-sectional views illustrating a contact fabrication method for a semiconductor device according to the present invention.

### DETAILED DESCRIPTION OF THE INVENTION

The embodiments of the present invention will be explained with reference to the accompanying drawings.

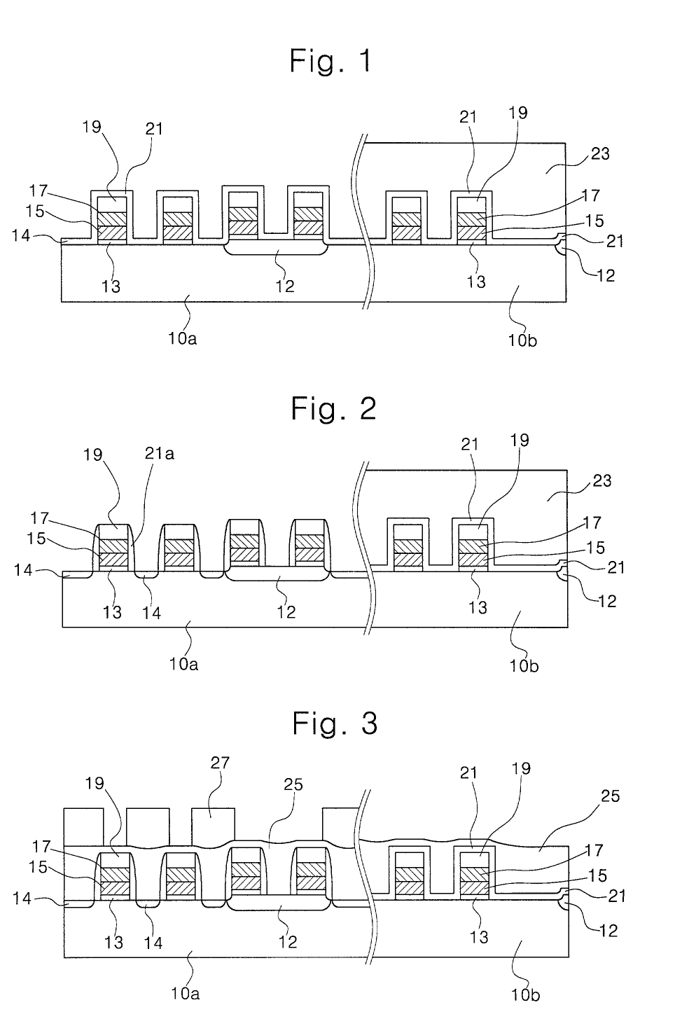

First, as shown in FIG. 1, a predetermined dopant is ion-implanted into silicon substrates 10a and 10b which are used as a semiconductor substrate for thereby forming a well, and the dopant is implanted into a channel portion of a transistor and a lower portion of a device isolation region, respectively. Thereafter, a device isolation oxide film 12 is formed on a portion which is used as a device isolation region in the semiconductor substrates 10a and 10b. A gate oxide film 13, a first polycrystal silicon 15 which is used as a gate conductive layer, a silicide film 17, and a mask insulation film 19 are sequentially formed on the entire surfaces of the semiconductor substrates 10a and 10b. The mask insulation film 19, the silicide film 17 and the first polycrystal silicon layer 15 are sequentially etched using the gate electrode patterning mask for thereby forming a gate electrode formed of the pattern of the first polycrystal silicon layer 15 and the pattern of the silicide film 17, and the pattern of the mask insulation film 19 which is self-aligned with the gate electrode is formed. At this time, the mask insulation film 19 is formed of an oxide film or a nitride film, and the silicide film 17 is formed of Ti, Mo, Nb, Ta, Cr, W, etc. for thereby decreasing the resistance of the gate electrode. In addition, the same may be formed of a heat-resisting metal such as W. The gate electrode may be formed of a single layer of the polycrystal silicon without using the silicide film.

Next, an insulation film 21 is formed on the entire surfaces of the resultant structure. A first photoresist film pattern 23 is formed on the resultant structure for opening a portion of the substrate on which the memory cell array is formed. At this time, the insulation film 21 is formed of a silicon nitride film.

As shown in FIG. 2, the insulation film 21 formed on the substrate 10a of the memory cell array is an isotopically etched using the first photoresist film pattern 23 as an etching mask for thereby forming a pattern of the mask insulation film 19 of the memory cell array 10a and a first spacer 21a at the lateral walls of the gate electrodes 15 and 17. In addition, a conductive dopant is ion-implanted into a portion of the substrate exposed by the first spacer 21a and the mask insulation film pattern 19 for thereby forming a source/drain junction 14. Thereafter, the first photoresist film pattern 23 is removed. The source/drain junction 14 may be formed in the LDD structure. In this case, the gate electrode is patterned, and then a low density dopant is ion-implanted.

As shown in FIG. 3, the second polycrystal silicon 25 is deposited on the front surface of the resultant structure and then the etching process is performed with respect to the resultant structure, and the thick second polycrystal silicon layer 25 is removed and then planerized. In addition, a second photoresist film pattern 27 is formed for forming the bit line contact plug and the electric potential storing electrode contact plug of the memory cell array 10a on the upper portion of the second polycrystal silicon layer 25.

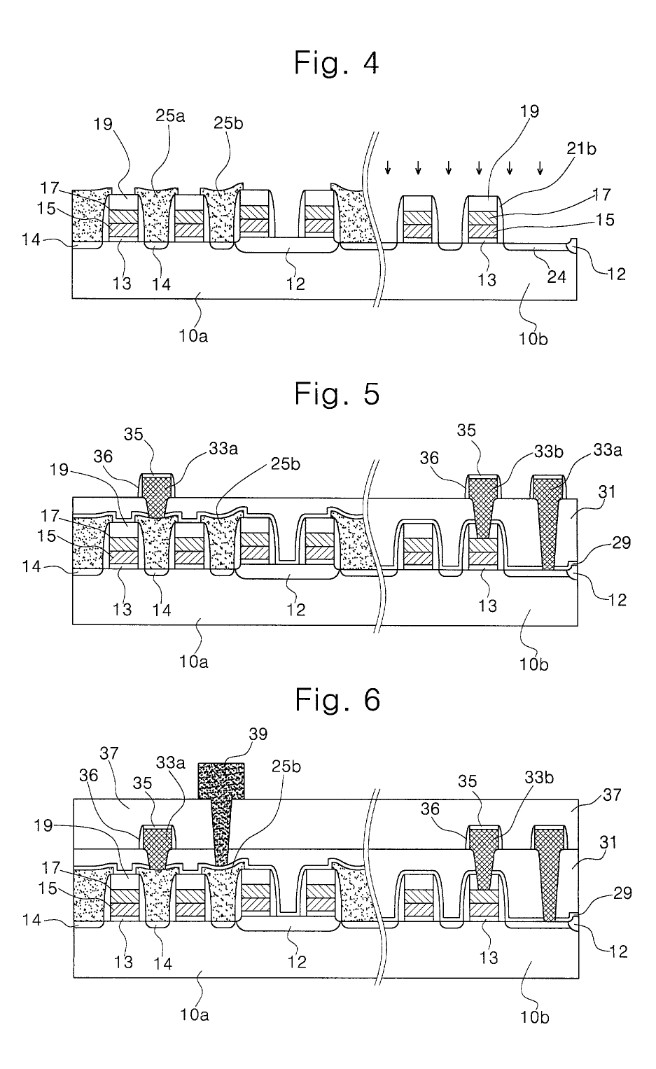

Next, as shown in FIG. 4, the exposed second polycrystal silicon layer 25 is patterned using the second photoresist film pattern 27 as an etching mask for thereby forming the bit line contact plug 25a and the electric potential storing electrode contact plug 25b contacting with the source and drain junction 14 of the substrate 10a of the memory cell array, and then the second photoresist film pattern 27 is removed.

Thereafter, a third photoresist film pattern(not shown) is formed to protect the substrate 10a of the memory cell array and to open a portion of the substrate of the peripheral circuit. The insulation film 12 of the peripheral circuit region 10b is anisotopically etched, and a second spacer 21b is formed on the gate electrode formed of the pattern of the first polycrystal silicon 15 and the pattern of the silicide film 17 and on the pattern lateral wall of the mask insulation film 19. Continuously, a dopant is ion-implanted into the substrate 10b of the peripheral circuit, and a source/drain junction 24 is formed on the substrate near the edges of the gate electrodes 15 and 17 and the second spacer 21b, and then the third photoresist film pattern is removed.

Next, as shown in FIG. 5, an IPO(InterPoly Oxide) and a BPSG(Borophospho Silicate Glass) are sequentially deposited on the entire surfaces of the resultant structure for thereby forming first interlayer insulation films 29 and 31, and the surface of the resultant structure is polished by a chemical mechanical polishing process for thereby planerizing the first interlayer insulation films 29 and 31.

Thereafter, a photo and etching process is performed using the bit line mask, and the first interlayer insulation films 31 and 29 are selectively etched, and a contact hole(not shown) is formed so that the surface of the substrate corresponding to the bit line contact plug 25a of the memory cell array 10a and the source/drain junction 24 of the peripheral circuit 10b are exposed. At this time, a contact hole is formed in the first interlayer insulation films 31 and 29 using the mask used for forming the word line of the peripheral circuit and the photo and etching processes so that the silicide film pattern 17 of the gate electrode formed on the substrate 10b of the peripheral circuit is exposed.

The wiring process of the semiconductor device is performed, and the bit line 33a contacting with the bit line contact plug 25a exposed through the contact hole and the substrate 10b of the peripheral circuit is formed, and a word line 33b connected with the gate electrode of the peripheral circuit is formed. At this time, the conductive material is deposited on the front surfaces of the first interlayer insulation films 29 and 31, and the conductive layers are patterned in the shape of the bit line and word line mask, and the mask nitride film 35 and the nitride film spacer 36 are formed on the upper portions and the lateral surfaces of the bit line 33a and the word line 33b formed of the patterned conductive layer for thereby preventing a short circuit with the bit lines 33 when forming the electric potential storing electrode.

As shown in FIG. 6, the second interlayer insulation film 37 is formed on the front surface of the resultant structure. The second and first interlayer insulation films 37 and 31 and 29 of the electric potential electrode contact plug 25a are sequentially removed for thereby forming an electric potential storing electrode contact hole(not shown), and the electric potential storing electrode 39 is buried into the electric potential electrode contact hole.

In the contact fabrication method for a semiconductor device according to the present invention, since an insulation spacer is formed on the inner wall of the contact hole after forming a contact hole exposing the bit line and electric potential storing electrode contact plugs, it is possible to prevent an electric insulation of the plug and bit lines.

In the semiconductor device having a bit line contact plug and surrounded by the insulation film on its upper surface of the bit line, the process margin of the contact formation is increased, and the junction leakage current is decreased, and a short circuit between the bit line and the electric potential storing electrode is prevented.

In the contact fabrication process of the semiconductor device according to another embodiment of the present invention, the processes of this embodiment are the same as the processes as shown in FIG. 2 except for the following processes. Namely, an insulation film pattern is formed on a portion of the contact plug of the second polycrystal silicon layer, and an insulation film spacer is formed on a lateral wall of the insulation film pattern, and the second polysilicon layer is patterned using the insulation film pattern and the insulation film pattern spacer as an etching mask for thereby forming a bit line and an electric potential storing electrode contact plug, and then the next processes are performed for thereby finally fabricating a semiconductor device.

As described above, in the contact fabrication method for a semiconductor device according to the present invention, the MOSFET is formed in a structure that the mask insulation film pattern is stacked on the gate electrode, and the insulation film spacer is formed on the lateral wall of the insulation pattern. In addition, the bit lint contact plug and the electric potential storing electrode contact plug contacting with the semiconductor substrate are formed on the portions of the bit line contact and the electric potential storing electrode contact, and the bit line and electric potential storing electrode contacting with the bit line contact plug and the electric potential storing electrode contact plug are formed, so that an enough fabrication margin for the neighboring gate electrode is obtained in the limited space for thereby preventing a predetermined damage due to the etching of the junction portion and decreasing the junction leakage current, whereby it is possible to implement a high integration of the semiconductor device. In addition, in the present invention, since the upper surfaces of the bit line or word line are encapsulated by the insulation film, a predetermined short circuit between the bit line or word line and the upper wiring portion may be prevented thus obtaining a good electrical characteristic.

Although the preferred embodiments of the present invention have been disclosed for illustrative purposes, those skilled in the art will appreciate that various modifications, additions and substitutions are possible, without departing from the scope and spirit of the invention as recited in the accompanying claims.

What is claimed is:

1. In a fabrication method for a semiconductor device having a memory cell array and a peripheral circuit, a contact fabrication method for a semiconductor device, comprising:
forming a gate electrode formed of more than one conductive layer and a mask insulation film pattern self-aligned with the electrode on a semiconductor substrate on which the memory cell array and peripheral circuit are formed;
forming a first spacer on a mask insulation film pattern of the substrate and a lateral wall of a gate electrode corresponding to the regions of the memory cell array;
forming a source and drain junction on the memory cell array region exposed by the first spacer and the gate electrode;
depositing a conductive film on the front surface of the substrate, patterning the conductive film, and forming a bit line contact plug and electric potential storing electrode contract plug contacting with the drain and source junction of the substrate of the memory cell array region;
forming a second spacer on the mask insulation film pattern of the substrate corresponding to the region of the peripheral circuit and a lateral wall of the gate electrode, respectively;
forming a source and drain junction at a region of the peripheral circuit exposed by the second spacer and mask insulation film pattern;
forming a first interlayer insulation film on the front surface of the resultant structure and forming a contact hole for exposing the bit line contact plug of the memory cell array and a part of surface of the source or drain junction of the peripheral circuit;
forming a bit line contacting with the bit line contact plug formed on the substrate of the memory cell array through the contact hole of the first interlayer insulation film and a source or drain junction surface of the peripheral circuit;
forming a second interlayer insulation film on the upper portion of the resultant structure and planerizing the surface of the resultant structure;
forming a contact hole on the planerized second interlayer insulation film, a part of the surfaces of the electric potential storing electrode contact plug of the memory cell array being exposed through the contact hole; and
forming an electric potential storing electrode contacting with the electric potential storing electrode contact plug through the contact hole of the second interlayer insulation film.

2. The method of claim 1, wherein said conductive layer of the gate electrode is formed in a two tier structure formed of a polysilicon layer and a silicide layer.

3. The method of claim 1, wherein said first and second spacers are formed of a silicon nitride film.

4. The method of claim 1, wherein said bit line contact plug is formed of a polycrystal silicon layer.

5. The method of claim 1, wherein said bit line contact plug and electric potential storing electrode contact plug are formed using two masks.

6. The method of claim 1, wherein an insulation film pattern of the gate electrode and a first spacer formed on a lateral wall of the same are used as an etching mask during the contact plug formation process.

7. The method of claim 1, wherein a contact hole is formed in the contact hole formation process of the first interlayer insulation film for thereby exposing a part of the gate electrode conductive layer of a peripheral circuit.

8. The method of claim 7, wherein a word line connected with the conductive layer of the gate electrode of the peripheral circuit is formed in the contact hole during the bit line formation process.

9. The method of claim 1, wherein said bit line is surrounded by a thin insulation film at its upper surface and lateral wall.

10. The method of claim 1, wherein a spacer formed of an insulation film is formed at an inner lateral wall of the contact hole of the second interlayer insulation film after the process, in which a contact hole is formed at the planerized second interlayer insulation film, a part of the surface of the electric potential storing electrode contact plug of the memory cell array being exposed through the contact hole.
